(19) United States
(12) Patent Application Publication
(10) Pub. No.: US 2011/0057293 A1
(43) Pub. Date: Mar. 10, 2011

(54) METAL-OXIDE-METAL CAPACITOR HAVING LOW PARASITIC CAPACITOR

(76) Inventor: Chun-An Tsai, Hsinchu County (TW)

(21) Appl. No.: 12/607,075

(22) Filed: Oct. 28, 2009

(30) Foreign Application Priority Data
Sep. 4, 2009 (TW) 098129826

(51) Int. Cl. H01L 29/92

(52) U.S. Cl. 257/532; 257/E29.342

(57) ABSTRACT

A metal-oxide-metal capacitor including a first metal layer of negative electric charge, a second metal layer of the negative electric charge, and at least a third metal layer formed between the first metal layer and the second metal layer, each of the at least a third metal layer including a plurality of first stripes of the negative electric charge and a plurality of second stripes of positive electric charge, wherein one of the plurality of first stripes is at a side of the third metal layer.

### BACKGROUND OF THE INVENTION

1. Field of the Invention

The present invention relates to a metal-oxide-metal capacitor, and more particularly, to a metal-oxide-metal capacitor having low parasitic capacitance between its positive electrodes and other points in an applied circuit.

2. Description of the Prior Art

A metal-oxide-metal (MOM) capacitor is a common semiconductor capacitor which offers high capacitance density, widely applied in mixed-signal integrated circuitry and RF circuitry. Manufacturing processes of a metal-oxide-metal capacitor has one mask process reduction than a metal-insulator-metal (MIM) capacitor, and is therefore simpler and more cost effective.

Please refer to FIG. 1 and FIG. 2. FIG. 1 is a plan view of an odd metal layer 11 of a prior interdigitated metal-oxide-metal capacitor 10, and FIG. 2 is a plan view of an even metal layer 12 of an interdigitated metal-oxide-metal capacitor 10. The metal-oxide-metal capacitor 10 uses metal stripes as its electrodes, which could be made of metal or polystalline silicon. Rlectrode patterns in each metal layers are interdigitated, while the adjoined stripes differ in electricity, and are labeled + or − respectively. The metal layer 11 comprises stripes 111, 113, and 115, coupled with a bus 117, and stripes 112, 114, and 116, coupled with a bus 118; the metal layer 12 comprises stripes 122, 124, and 126, coupled to a bus 128, and stripes 121, 123, and 125, coupled to a bus 127. The stripes of same electricity in different metal layers are electrically connected with each other through vias on the bus, which are marked by oblique lines.

As shown in FIG. 1 and FIG. 2, electrical polarity of each strip is different from adjoined stripes of a same layer. Therefore, a cross-section diagram of the metal-oxide-metal capacitor 10 can be illustrated with FIG. 3. In the metal-oxide-metal capacitor 10, the parasitic capacitance between its electropositive stripes and other points in an applied circuit is identical to the parasitic capacitance between its electronegative stripes and other points. Please note that in most of the common circuits, such as analog-to-digital converters, digital-to-analog converters, sample and hold circuits, and filter circuits, the input port of an operational amplifier is overly sensitive. Accordingly, the parasitic capacitance should be possibly minimized not to affect the efficiency of operational amplifier. Nevertheless, for the metal-oxide-metal capacitor 10, the parasitic capacitance between its electropositive stripes and other points is underdeveloped to be small enough, and is therefore not applicable to be used at the input port of an operational amplifier.

Besides the interdigitated metal-oxide-metal capacitor 10, there is still another kind of metal-oxide-metal capacitor that can be formed by prior semiconductor manufacturing process. Please refer to FIG. 4, which is a cross-section view of a prior parallel plate metal-oxide-metal capacitor 40. The metal-oxide-metal capacitor 40 is formed by staggered metal layers 41 to 45 of the same size of area and dielectric layers, which are omitted in FIG. 4. Each metal layer is a plate electrode, and the arrangements of plate electrodes of different electrical polarity are staggered. Similar to the interdigitated metal-oxide-metal capacitor 10, in the parallel plate metal-oxide-metal capacitor 40, the parasitic capacitance between its electropositive stripes and other points in an applied circuit is identical to the parasitic capacitance between its electronegative stripes and other points. Accordingly, the parallel plate metal-oxide-metal capacitor 40 is also less applicable to be used at the input port of operational amplifier.

In addition, when inaccuracy of the etching process is considered, the edges of each plate electrode of metal-oxide-metal capacitor 40 are not as neat as illustrated in FIG. 4, but thoroughly uneven. The parasitic capacitance between the edge of a plate electrode and the edge of another plate electrode above can never be identical to the parasitic capacitance between the edge of the plate electrode and the edge of another plate electrode below, that is, parasitic capacitance resulting from the uneven electrode edges downgrade the precision of the metal-oxide-metal capacitor 40. Furthermore, while utilizing metal-oxide-metal capacitor 40 at the input port of an operational amplifier, the variation of parasitic capacitance derived from the uneven electrode edges may result in mismatch of capacitors used to design the gain of the operational amplifier, and further causes deviation from an ideal gain of the operational amplifier.

### SUMMARY OF THE INVENTION

It is therefore an objective of the present invention to provide a metal-oxide-metal capacitor having low parasitic capacitance between its positive electrodes and other points.

The present invention discloses a metal-oxide-metal capacitor comprising a first metal layer of negative electric charge, a second metal layer of the negative electric charge, and at least a third metal layer formed between the first metal layer and the second metal layer, each of the at least a third metal layer including a plurality of first stripes of the negative electric charge and a plurality of second stripes of positive electric charge, wherein one of the plurality of first stripes is at a side of the third metal layer.

The present invention further discloses a metal-oxide-metal capacitor comprising a plurality of first metal layer of a first electric charge and at least a second metal layer of a second electric charge, each of the at least a second metal layer being formed between two adjoined ones of the plurality of first metal layers, and the area of each of the at least a second metal layer is smaller than that of an adjoined one of the plurality of first layers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a plan view of an odd metal layer of a prior interdigitated metal-oxide-metal capacitor.

FIG. 2 is a plan view of an even metal layer of the interdigitated metal-oxide-metal capacitor shown in FIG. 1.

FIG. 3 is a cross-section view of the interdigitated metal-oxide-metal capacitor shown in FIG. 1.

FIG. 4 is a cross-section view a prior parallel plate metal-oxide-metal capacitor.

FIG. 5 is a cross-section view of an interdigitated metal-oxide-metal capacitor according to an embodiment of the present invention.

FIG. 6 is a plan view of an odd metal layer of the metal-oxide-metal capacitor shown in FIG. 5.

FIG. 7 is a plan view of an even metal layer of the metal-oxide-metal capacitor shown in FIG. 5.

FIG. 8 and FIG. 9 are cross-section views of interdigitated metal-oxide-metal capacitors according to embodiments of the present invention.

FIG. 10 is a cross-section view of a parallel plate metal-oxide-metal capacitor according to an embodiment of the present invention.

FIG. 11 is a planar perspective view of the metal-oxide-metal capacitor shown in FIG. 10.

FIG. 12 is a planar perspective view of the metal-oxide-metal capacitor according to an embodiment of the present invention.

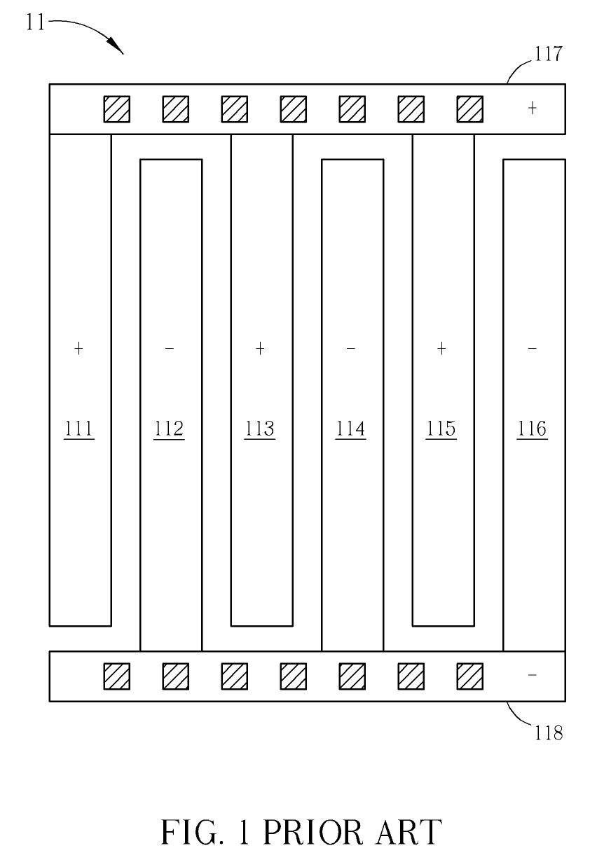

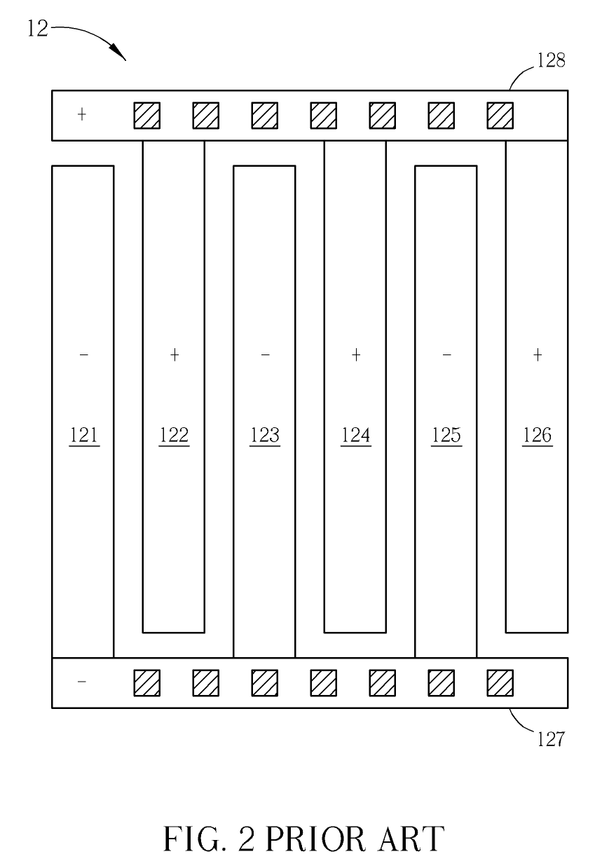

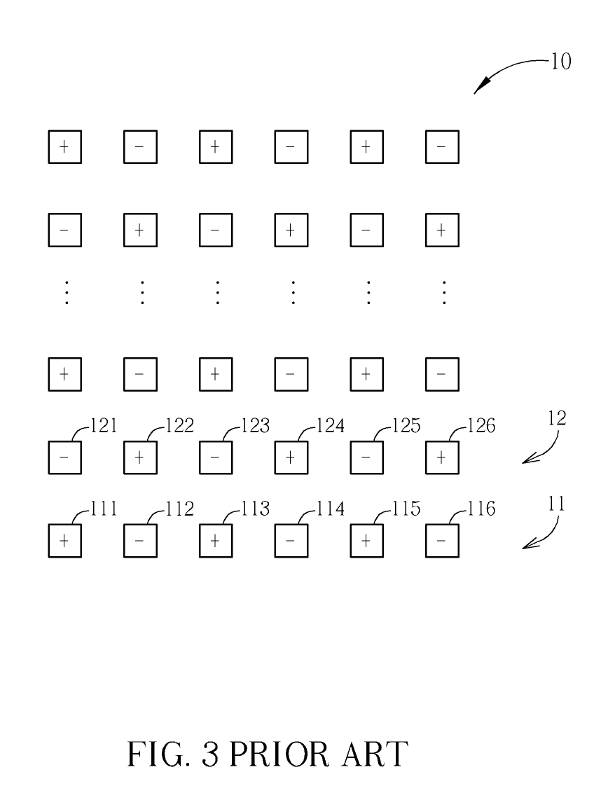

### DETAILED DESCRIPTION

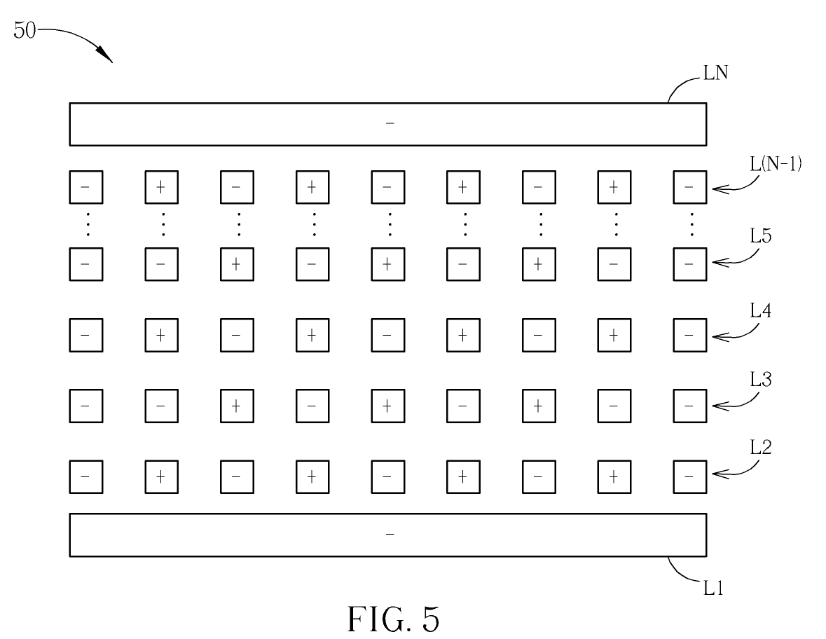

Please first refer to FIG. 5, which is a cross-section view of an interdigitated metal-oxide-metal capacitor 50 according to an embodiment of the present invention. The metal-oxide-metal capacitor 50 comprises metal layers L1-LN, wherein the first layer (which is also the bottom layer) and the N^{th} layer (which is also the top layer) are plate electrodes. Metal stripes in each of the second layer to the (N−1)^{th} layer are utilized as electrodes, and the charge carried by which are labeled + or − respectively. Dielectric layers lie between metal layers, and are omitted in the figures. The number of stripes illustrated in the following figures is only one embodiment, which the present invention includes, but is not limited to. The bottom layer and the top layer of the metal-oxide-metal capacitor 50 are both electronegative plate electrodes rather than staggered electropositive and electronegative stripes, moreover, in each of the second layer to the (N−1)^{th} layer, stripes at both sides are electronegative, while others are electropositive and electronegative stripes staggered respectively. Each electropositive strip adjoins horizontally to electronegative stripes of the same metal layer, and adjoins vertically to electronegative stripes of the adjoined metal layers.

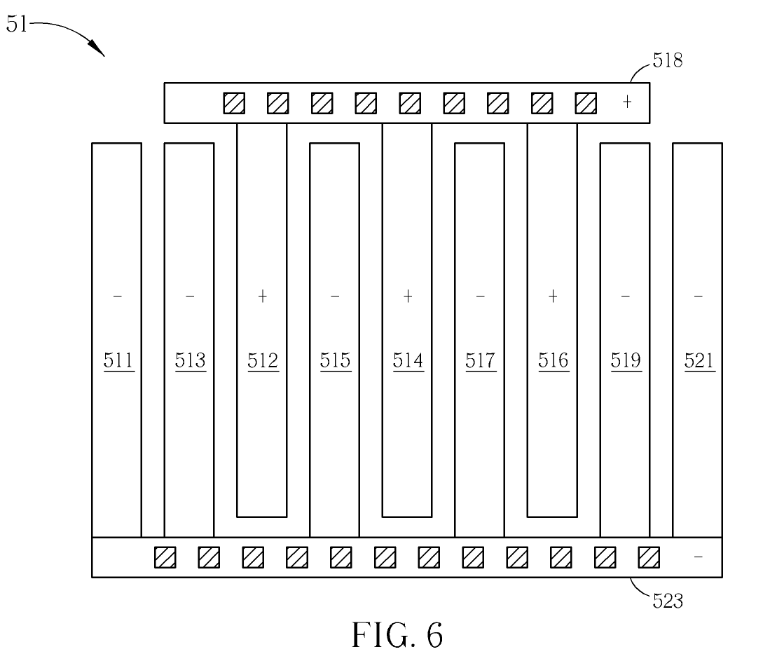

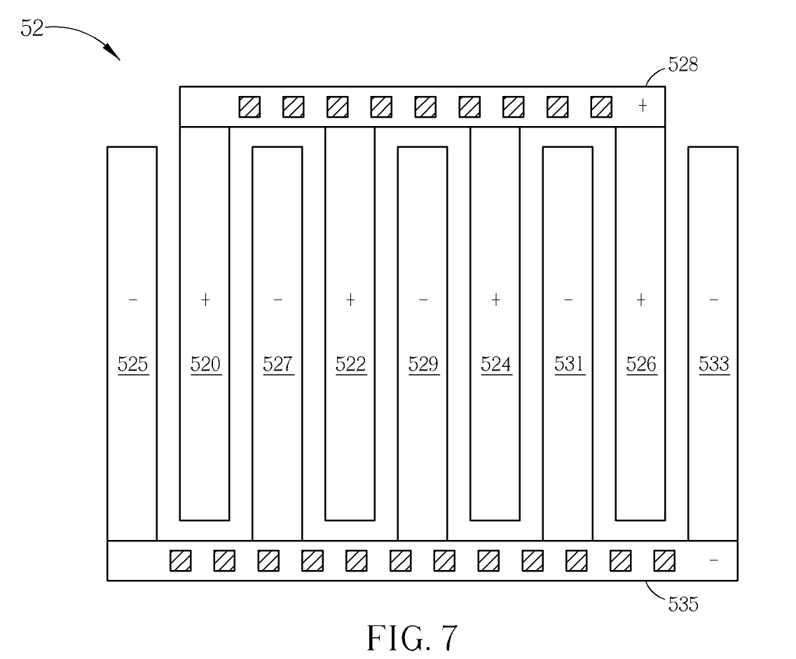

Please refer to FIG. 6 and FIG. 7, which are plan views of an odd metal layer 51 and an even metal layer 52 of the second layer to the (N−1)^{th} layer in the metal-oxide-metal capacitor 50 of FIG. 5 respectively. The metal layer 51 comprises electronegative stripes 511, 513, 515, 519, and 521, coupled with a bus 523, and electropositive stripes 512, 514, and 516, coupled with a bus 518; the metal layer 52 comprises electronegative stripes 525, 527, 529, 531, and 533, coupled with a bus 535, and electropositive stripes 520, 522, 524, and 526, coupled with a bus 528. All electropositive stripes of the metal layer are electrically connected with each other through vias on the bus, marked by oblique line. All electronegative of the metal layer are electrically connected with each other through vias on the bus, and are electrically connected with electronegative plate electrodes of the bottom layer and the top layer. In addition, there are vias on each electronegative stripe at both sides of each odd metal layer, which are used to electrically connect the odd metal layers.

From the above, it can be seen in the meal-oxide-metal capacitor 50 that the electronegative plate electrodes of the bottom layer and the top layer and electronegative stripes at both sides of metal layers other than the bottom and the top layer encompass its inner electropositive stripes, and thereby the parasitic capacitance between its electropositive stripes and other points in an applied circuit decreases with the shelter of peripheral electronegative plate electrodes and stripes. Accordingly, the metal-oxide-metal capacitor 50 is more applicable to parasitic capacitance sensitive circuits, such as at an input port of an operational amplifier.

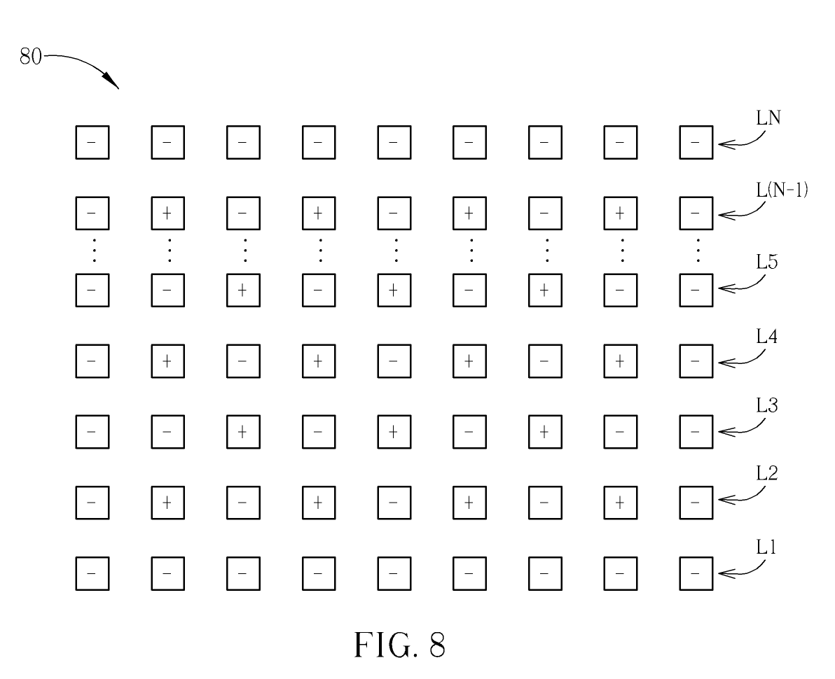

Please note that the metal-oxide-metal capacitor 50 is only one embodiment of the present invention, and those skilled in the art can make alterations and modifications accordingly. Please refer to FIG. 8, which is a cross section view of an interdigitated metal-oxide-metal capacitor 80 according to an embodiment of the present invention. The metal-oxide-metal capacitor 80 is similar to the metal-oxide-metal capacitor 50, but differs in the constitution of its top layer and bottom layer—the top layer and the bottom layer of the metal-oxide-metal capacitor 80 are electronegative stripes instead of plate electrodes. In the metal-oxide-metal capacitor 80, the electronegative stripes of the bottom layer and the top layer and the electronegative stripes at both sides of each metal layer other than the bottom and the top layers encompass its inner electropositive stripes to reduce the parasitic capacitance between its electropositive stripes and other points in an applied circuit, but the reduction effect of the metal-oxide-metal capacitor 80 is inferior to that of the metal-oxide-metal capacitor 50. Those skilled in the art can deduce diagrams of each metal layer and manufacturing processes by the cross-section view of the metal-oxide-metal capacitor 80.

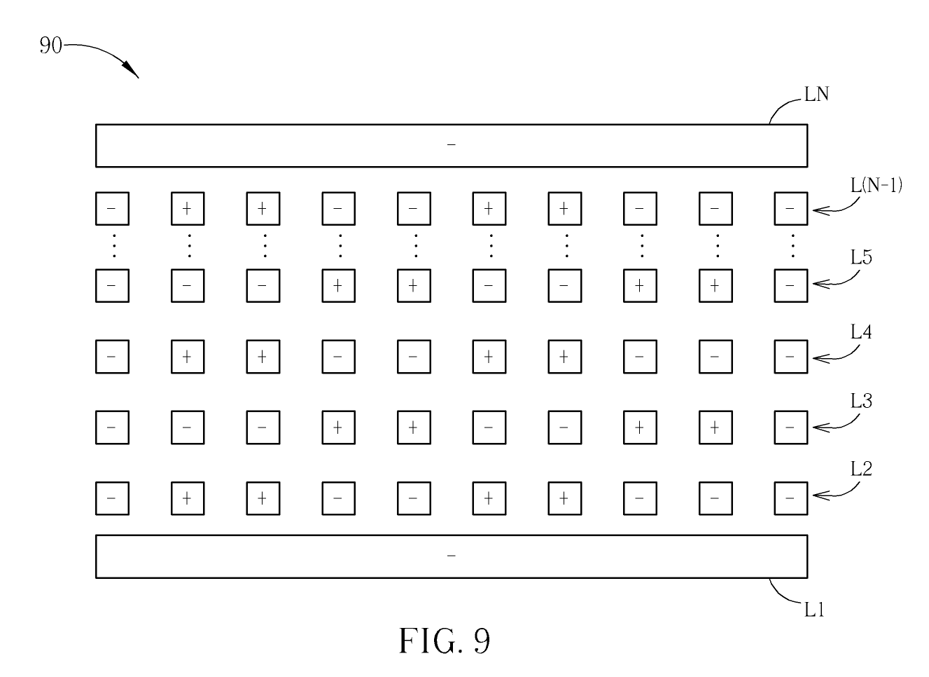

Please refer to FIG. 9, which is a cross-section view of an interdigitated metal-oxide-metal capacitor 90 according to an embodiment of the present invention. The metal-oxide-metal capacitor 90 comprises metal layers L1-LN, wherein the top layer and bottom layer are plate electrodes, and metal stripes of each of the second layer to (N−1)^{th} layer are used as electrodes. The metal-oxide-metal capacitor 90 is similar to the metal-oxide-metal capacitor 50, but differs in the arrangement of stripes of the second layer to (N−1)^{th} layer—except the necessary electronegative stripes at both sides of each metal layer, other stripes are staggered by two rather than one. Similarly, the bottom layer, the top layer, and the electronegative stripes at both sides of each metal layer of the metal-oxide-metal capacitor 90 encompass its inner electropositive stripes, so that the parasitic capacitance between its electropositive stripes and other points is reduced, and is therefore applicable to be used at an input of the operational amplifier.

In detail, as to an interdigitated metal-oxide-metal capacitors according to an embodiment of the present invention, in each layer of the second layer to (N−1)^{th} layer, except the necessary electronegative stripes at both sides, other electronegative stripes can be regarded as combination of a plurality of groups, and all the electropositive stripes can also be regarded as combination of a plurality of groups. It can also be induced from the embodiments in FIG. 5 to FIG. 9 that each electropositive group comprises at least one electropositive strip, and each electronegative group comprises at least one electronegative strip. Each group of electropositive stripes adjoins horizontally to groups of electronegative stripes of the same metal layer, and adjoins vertically to groups of electronegative stripes of the adjoined metal layers.

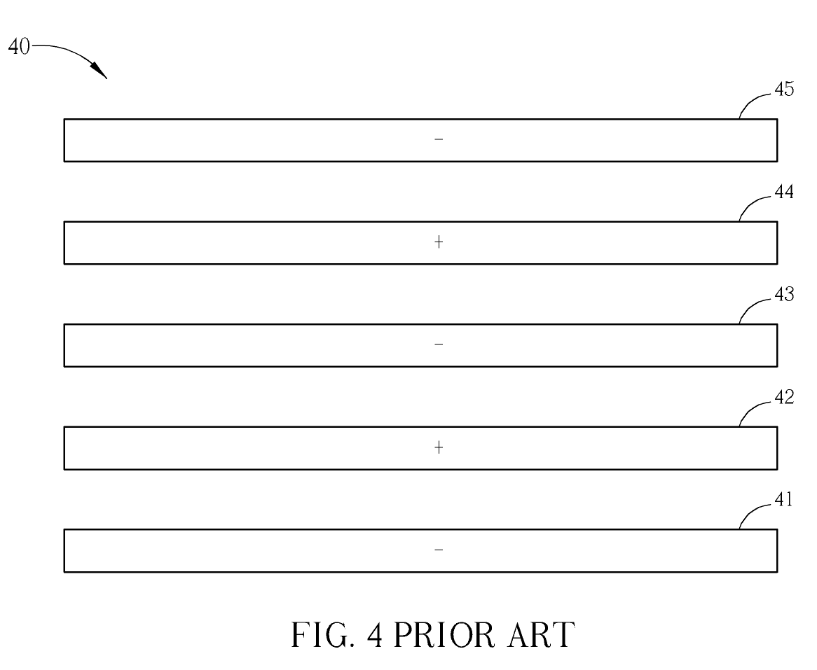

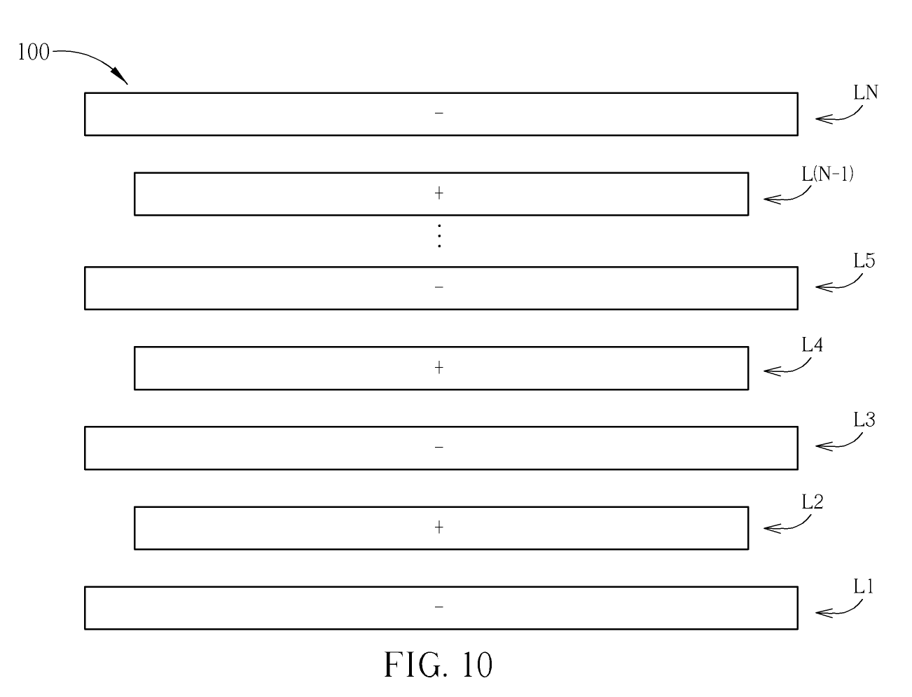

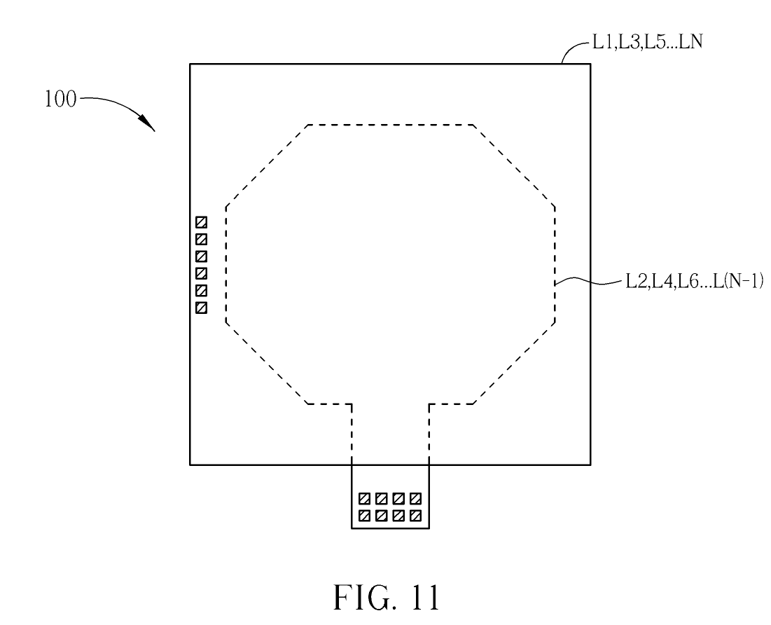

Please refer to FIG. 10, which is a cross-section view of a parallel plate metal-oxide-metal capacitor 100 according to an embodiment of the present invention. The metal-oxide-metal capacitor 100 is formed by staggered metal layers L1-LN and dielectric layers, which are omitted in FIG. 4. Each metal layer is a plate electrode, and the arrangements of plate electrodes of different electricity are staggered. Odd metal layers L1, L3, L5, . . . , and LN are electronegative plate electrodes, and even metal layers L2, L4, L6, . . . , and L(N−1) are electropositive plate electrodes. The size of the area of each electropositive plate electrode is smaller than that of two vertically adjoined electronegative plate electrodes. Please refer to FIG. 11, which is a planar perspective view of the metal-oxide-metal capacitor 100, wherein odd metal layers are marked by continuous lines, and even metal layers are marked by dot lines. As shown in FIG. 11, an additional electrode area is formed at a side of each electropositive plate electrode, and the additional area of each electropositive plate electrode are electrically connected with each other through vias, which are marked by oblique lines. Similarly, all electronegative plate electrodes are also electrically connected with each other through vias at the same side.

It can be seen from FIG. 10 and FIG. 11 that the top and bottom layers of the parallel plate metal-oxide-metal capacitor 100 are both electronegative plate electrodes, wherein the size of the area of each electropositive plate electrode is smaller than that of its adjoined electronegative plate electrodes. Thereof, the parasitic capacitance between its electropositive stripes and other points decreases with the shelter of peripheral electronegative plate electrodes. Compared to the prior parallel plate metal-oxide-metal capacitor 40 in FIG. 4, the parallel plate metal-oxide-metal capacitor 100 is more applicable to be used in parasitic capacitance sensitive circuits, such as an input port of an operational amplifier.

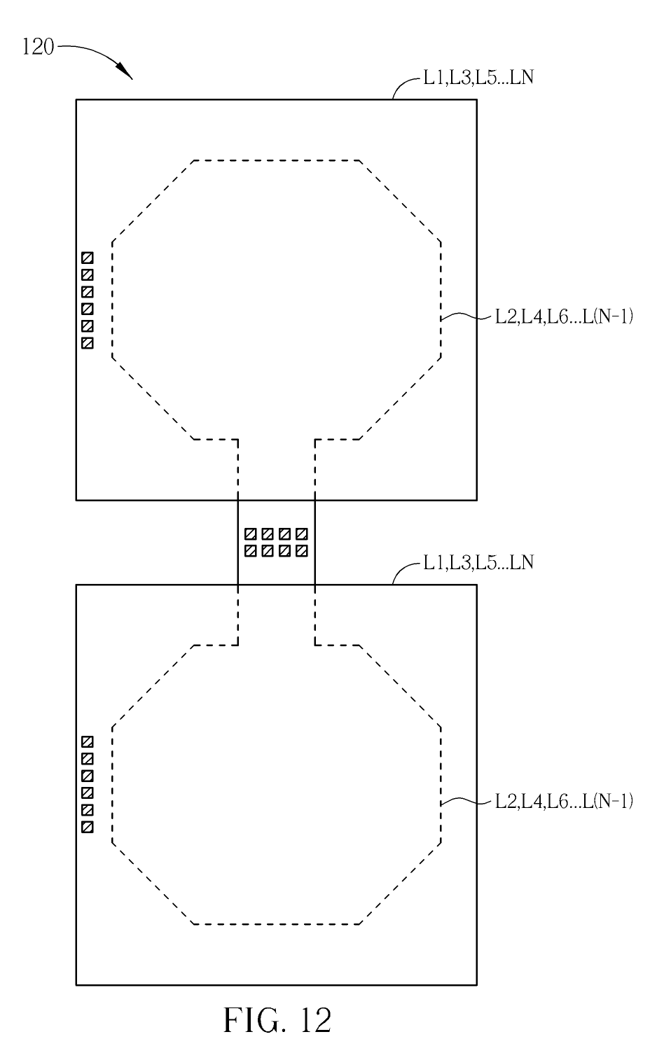

Please note that the parallel plate metal-oxide-metal capacitor 100 shown in FIG. 10 and FIG. 11 is a two-terminal capacitor. However, the concept of reducing size of the electropositive plate electrodes to decrease parasitic capacitance can also be performed to form a three-terminal capacitor. Please refer to FIG. 12, which is a planar perspective view of the metal-oxide-metal capacitor 120 according to an embodiment of the present invention. The metal-oxide-metal capacitor 120 is a three-terminal capacitor, wherein the odd metal layers, which are electronegative plate electrodes, are marked by continuous lines; the even metal layers, which are electropositive plate electrodes, are marked by dot lines; the vias are marked by oblique lines. Those skilled in the art can deduce the design of three-terminal capacitor in FIG. 12 from the concept revealed in FIG. 10, and is not repeated herein.

Overall, the interdigitated metal-oxide-metal capacitor and the parallel plate metal-oxide-metal capacitor provided by the present invention greatly reduces the parasitic capacitance between its positive electrodes and other points in an applied circuit, therefore, the metal-oxide-metal capacitor of the present invention is more applicable for an operational amplifier circuit in analog-to-digital converters, digital-to-analog converters, and sample and hold circuits.

Those skilled in the art will readily observe that numerous modifications and alterations of the device and method may be made while retaining the teachings of the invention.

What is claimed is:

1. A metal-oxide-metal capacitor comprising:
a first metal layer of a first electric charge;
a second metal layer of the first electric charge; and
at least a third metal layer formed between the first metal layer and the second metal layer, each of the at least a third metal layer including a plurality of first stripes of the first electric charge and a plurality of second stripes of the second electric charge, wherein one of the plurality of first stripes is at a side of the third metal layer.

2. The metal-oxide-metal capacitor of claim 1, wherein the first electric charge is negative, and the second electric charge is positive.

3. The metal-oxide-metal capacitor of claim 1, wherein the first metal layer and the second metal layer are plate electrodes.

4. The metal-oxide-metal capacitor of claim 1, wherein the plurality of first stripes except which at two sides of each of the third metal layer form a plurality of first groups, and the plurality of second stripes form a plurality of second groups.

5. The metal-oxide-metal capacitor of claim 4, wherein each first group of the plurality of first groups comprises at least a first strip, and each second group of the plurality of second groups comprises at least a second strip.

6. The metal-oxide-metal capacitor of claim 4, wherein each second group of the plurality of second groups of one of the at least a third layer is adjoined to a first group of the same third layer.

7. The metal-oxide-metal capacitor of claim 4, wherein each second group of the plurality of second groups of one of the at least a third layer is adjoined to a first group of an adjoined third layer.

8. The metal-oxide-metal capacitor of claim 1, wherein the first metal layer comprises a plurality of stripes of the first electric charge.

9. The metal-oxide-metal capacitor of claim 1, wherein the second metal layer comprises a plurality of stripes of the first electric charge.

10. The metal-oxide-metal capacitor of claim 1, wherein the plurality of first stripes of each of the at least a third metal layer are electrically connected with each other.

11. The metal-oxide-metal capacitor of claim 1, wherein the plurality of second stripes of each of the at least a third metal layer are electrically connected with each other.

12. A metal-oxide-metal capacitor comprising:
a plurality of first metal layer of a first electric charge; and
at least a second metal layer of a second electric charge, each of the at least a second metal layer being formed between two adjoined ones of the plurality of first metal layers, and the area of each of the at least a second metal layer is smaller than that of an adjoined one of the plurality of first layers.

13. The metal-oxide-metal capacitor of claim 12, wherein the plurality of first metal layers are plate electrodes.

14. The metal-oxide-metal capacitor of claim 12, wherein the at least a second metal layer is plate electrode.

15. The metal-oxide-metal capacitor of claim 12, wherein the plurality of first metal layer are electrically connected with each other.

16. The metal-oxide-metal capacitor of claim 12, wherein the at least a second metal layer are electrically connected with each other.
